(19) United States
(12) Patent Application Publication
(10) Pub. No.: US 2007/0249146 A1
(43) Pub. Date: Oct. 25, 2007

(54) Protective tape applying method

(75) Inventor: Takatoshi Masuda, Tokyo (JP)

Correspondence Address: BRINKS HOFER GILSON & LIONE, P.O. BOX 10395, CHICAGO, IL, 60610, US

(73) Assignee: DISCO CORPORATION

(21) Appl. No.: 11/787,627

(22) Filed: Apr. 17, 2007

(30) Foreign Application Priority Data
Apr. 19, 2006 (JP) 2006-115399

(51) Int. Cl. H01L 21/00

(52) U.S. Cl. 438/464; 438/460; 438/113

(57) ABSTRACT

A protective tape applying method includes: preparing a substrate which has plural devices formed on a surface of the substrate; and holding the substrate on a chuck table such that a rear surface of the substrate is chucked by the chuck table and the surface of the substrate is exposed. The method further includes: straining a protective tape on the surface of the substrate held by the chuck table such that the protective tape faces the surface of the substrate; and pressing the protective tape on a center portion of the substrate or a portion proximate to the center portion by using a pressing roller having a pressing width which is at least equal to or wider than a diameter of the substrate. The method further includes: rolling the pressing roller on the substrate while the pressing roller presses the protective tape on the substrate, so that the protective tape is applied onto the entire surface of the substrate.

This application claims priority under 35 U.S.C. §119 to Japanese Patent Application No. JP2006-115399 filed Apr. 19, 2006, the entire content of which is hereby incorporated by reference.

### BACKGROUND OF THE INVENTION

1. Field of the Invention

The present invention relates to a method for applying a protective tape onto a thin plate-like substrate (for example, semiconductor wafer) composed of a relatively brittle material. In particular, the present invention relates to an improved method for applying a protective tape onto a substrate without a damage occurring on the substrate.

2. Description of Related Art

In general, semiconductor chips, which are used in various electronic apparatuses, are produced by the following method. That is, grid-like rectangular regions are defined by predetermined division lines on a disc-shaped semiconductor wafer, and electronic circuits (for example, Integrated Circuits (ICs) and Large Scale Integrations (LSIs)) are formed on surfaces of the rectangular regions. Next, a rear surface of the wafer is ground so as to be thinned. The wafer is divided along the predetermined division lines. As a result, semiconductor chips are produced. In thinning by grinding of a rear surface of semiconductor wafer, in general, a semiconductor wafer is chucked and held on a vacuum chuck type chuck table such that a rear surface, which is subjected to grinding, is exposed. Next, rotating grinding stones are pressed on the rear surface of the semiconductor wafer, so that the semiconductor wafer is thinned. In this case, a protective tape is applied onto a surface of the semiconductor wafer so as to prevent generation of damage to electronic circuits formed on the surface, the generation of damage being caused by directly contact of the surface onto the chuck table.

In recent years, electronic apparatuses are greatly improved in compactness and thinness. In accordance with this, since a semiconductor chip is required to be thinner, a semiconductor wafer is required to be thinner than previously. However, when the semiconductor wafer is thinned, the rigidity of the semiconductor wafer is decreased. Due to this, it is difficult to handle the semiconductor wafer after the thinning, and cracking easily occurs in the semiconductor wafer. A protective tape, which is applied onto a surface of the semiconductor wafer when the thinning is performed, provides rigidity to the semiconductor wafer, and the handling of the semiconductor wafer is improved by the protective tape. However, when the semiconductor wafer is subjected to processing with heating after the thinning, the protective tape is disadvantageous in heat resistance.

In order to solve this problem caused by the thinning, only the rear surface of circular device forming region, which has semiconductor chips formed on the surface, is ground so as to be thinned, and a ring-shaped peripheral extra region around the device forming region is thereby formed as a relatively thick reinforcing portion. As a result, the rigidity is provided to the semiconductor wafer, so that the semiconductor wafer is easily handled. In this case, since the rear surface is ground, the thick peripheral reinforcing portion projects on the rear surface, and the semiconductor wafer has a recessed shape in cross section. For example, the technique, in which only the peripheral portion is allowed to be thick, has been disclosed in Japanese Unexamined Patent Application Publication No. 2004-281551.

For example, for the above processing with heating, a technique is used in which a metal film composed of Au or the like is provided to a rear surface of the semiconductor wafer by deposition, sputtering, or the like. For example, a technique is used in which impurities are diffused in the semiconductor wafer by ion implantation from the rear surface of the semiconductor wafer. When the rigidity is provided by the protective tape, the processing temperature needs to be lower in a case in which the protective tape has insufficient heat-resistance. Due to this, the processing was more time-consuming in this case than in normal cases. In contrast, when a peripheral reinforcing portion is formed and a protective tape is not used, heating can be smoothly performed without consideration of heat effects. In order to protect a surface of semiconductor wafer when a peripheral reinforcing portion is finally removed by grinding or cutting after heating, if necessary, a protective tape is applied onto the surface of the semiconductor wafer again. For example, a method for applying a protective tape onto a semiconductor wafer is disclosed in Japanese Unexamined Patent Application Publication No. 2005-223190.

In the protective tape applying method disclosed in Japanese Unexamined Patent Application Publication No. 2005-223190, a roller presses a protective tape onto a surface of semiconductor wafer and the protective tape is applied thereonto by rolling the roller. In the applying of the protective tape, the applying load of the roller is changed depending on the applied width of the protective tape onto the semiconductor wafer, and a load per unit area of the entire surface of the semiconductor wafer is uniform, so that generation of warp and deformation may be inhibited. However, in this method, since it is necessary to use an advanced control for changing the pressing load of the roller while the roller rolls, it is difficult to use this control in practice. In addition, since the pressing load is proximate to 0 at an end portion of the wafer which has the narrowest applied width of the protective tape, the adhesive strength of the protective tape on the end portion of the wafer is small by any means. Due to this, since the protective tape may be easily peeled from the end portion, a problem may be caused such that the protective tape on the end portion may float therefrom.

### SUMMARY OF THE INVENTION

Therefore, an object of the present invention is to provide a protective tape applying method which can easily perform applying of a protective tape onto a surface of substrate by effectively dispersing a load, which is provided onto the surface thereof by the pressing roller, without warp and breakage occurring on the substrate.

According to one aspect of the present invention, a protective tape applying method includes: preparing a substrate which has plural devices formed on a surface of the substrate; and holding the substrate on a chuck table such that a rear surface of the substrate is chucked by the chuck table and the surface of the substrate is exposed. The method further includes: straining a protective tape on the surface of the substrate held by the chuck table such that the protective tape faces the surface of the substrate; and pressing the protective tape on a center portion of the substrate or a portion proximate to the center portion by using a pressing roller having a pressing width which is at least equal to or wider than a diameter of the substrate. The method further includes: rolling the pressing roller on the substrate while the pressing roller presses the protective tape on the substrate, so that the protective tape is applied onto the entire surface of the substrate.

The point of the protective tape applying method of the present invention is as follows. That is, first, in the rolling for applying the protective tape onto the substrate in practice, the pressing roller presses the protective tape onto the center portion of the substrate or the portion proximate to the center portion, at which the pressing width of the pressing roller onto the substrate is maximum. Next, in the rolling of the pressing roller, the pressing roller rolls on the entire surface of the substrate, so that the protective tape is applied on the substrate. In one example for rolling the pressing roller on the entire surface of the substrate, the protective tape is applied onto the almost half of the surface by rolling the pressing roller from the center portion of the substrate to the one end portion thereof. Next, the pressing roller rolls from the one end portion of the substrate to the other end portion thereof, so that the protective tape is applied onto the entire surface of the substrate.

In the protective tape applying method of the present invention, since the applying load, that is, the load of the pressing roller in the initial applying of the protective tape is not provided onto the end portion of the substrate but is provided onto the center portion of the substrate or the portion proximate to the center portion, the load of the pressing roller is effectively dispersed, thereby being minimal or proximate to the minimum. Therefore, breakage of the end portion of the substrate onto which the load is locally provided by the pressing roller can be prevented, so that the protective tape can be reliably applied onto the substrate. Since providing of excessive load to the end portion of the substrate is avoided in the initial applying of the protective tape, the load of the pressing roller onto the substrate can be constant in the following rolling of the pressing roller. Since it is unnecessary to change the load of the pressing roller in this manner, the protective tape can be easily applied.

Instead of initial pressing the protective tape by the pressing roller onto the center portion of the substrate or the portion proximate to the center portion in the above manner, a support member, on which the pressing roller rolls, can be provided around the substrate so as to have a surface which is flush with the surface of the substrate. That is, according to another aspect of the present invention, a protective tape applying method includes: preparing a substrate which has plural devices formed on a surface of the substrate; and holding the substrate on a chuck table such that a rear surface of the substrate is chucked by the chuck table and the surface of the substrate is exposed. The method further includes: straining a protective tape on the surface of the substrate held by the chuck table such that the protective tape faces the surface of the substrate; providing a support member around the substrate. The support member has a surface which is flush with the surface of the substrate. The method further includes: rolling a pressing roller on the substrate while the pressing roller presses the protective tape on the substrate and the supporting member which is around the substrate. The pressing roller has a pressing width which is at least equal to or wider than a diameter of the substrate. Therefore, the protective tape is applied onto the entire surface of the substrate.

In the protective tape applying method of the present invention, the pressing portion of the pressing roller onto the substrate may not be limited. In a typical example, the pressing roller rolls from the one end portion of the substrate to the other end portion thereof, so that the protective tape can be applied onto the surface of the substrate. In this example, since in the rolling of the pressing roller, the pressing roller rolls on the substrate and the supporting member which is around the substrate, the load provided from the substrate is dispersed. Therefore, breakage of the substrate caused by providing an excessive load onto the substrate can be prevented, so that the protective tape can be reliably applied onto the substrate, and the load of the pressing roller onto the substrate can be constant in the rolling of the pressing roller. As a result, the protective tape can be easily applied.

Since in the protective tape applying method of the present invention, the applying load of the pressing roller onto the substrate can be effectively dispersed, the protective tape applying method is desirably used for applying a protective tape onto a substrate (for example, semiconductor wafer) which is very thin. For example, the substrate has a device forming region on which the devices are formed, and at least the device forming region of the substrate has a thickness of 200 μm or less. The protective tape applying method is desirably used for applying a protective tape onto a surface of substrate in which the device forming region is thinned by forming the peripheral reinforcing portion described above. That is, the substrate may have a non-device forming region which is formed around the device forming region and has no device, and a region of the rear surface of the substrate, which corresponds to the device forming region, may be formed to have a recessed shape which is thinner than the non-device forming region.

In the protective tape applying method of the present invention, when the protective tape is pressed and applied onto the surface of the substrate by the pressing roller, the load of the pressing roller can be effectively dispersed and can be constant. Therefore, the applying of the protective tape can be easily performed without breakage of the substrate occurring.

### BRIEF DESCRIPTION OF THE DRAWINGS

FIGS. 1A and 1B are a perspective view and a side view which show a semiconductor wafer onto which a protective tape is applied in an embodiment according to the present invention.

FIG. 2 is a perspective view showing a grinding apparatus which is used for forming a recess by grinding and thinning a portion of a rear surface of semiconductor wafer, which corresponds to the device forming region

FIG. 3 is a side view of the grinding apparatus shown in FIG. 2.

FIGS. 4A and 4B are a perspective view and a cross sectional view which show a semiconductor wafer having a recess formed on a rear surface of semiconductor wafer.

FIGS. 5A to 5D are front views showing a protective tape applying method of the embodiment in process order.

FIGS. 6A to 6C are front views showing a protective tape applying method of the embodiment in process order.

FIGS. 7A to 7C are front views showing a protective tape applying method of another embodiment according to the present invention.

FIG. 8 is a plain view showing the protective tape applying method of the another embodiment.

### DETAILED DESCRIPTION OF THE INVENTION

A protective tape applying method of an embodiment according to the present invention will be explained hereinafter with reference to the drawings.

### 1. Semiconductor Wafer

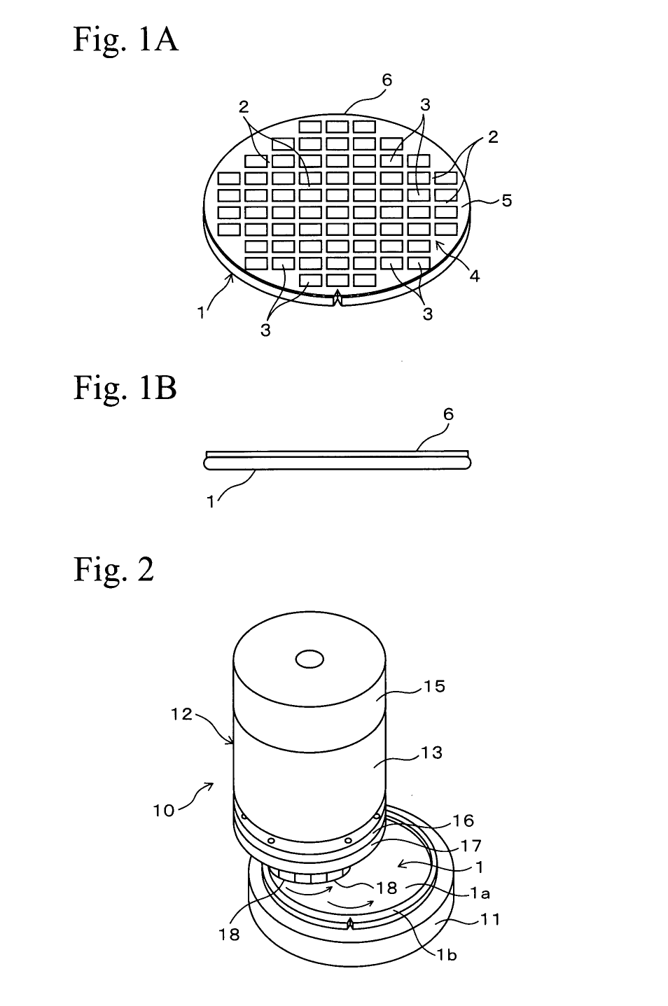

In FIGS. 1A and 1B, reference numeral 1 denotes a disc-shaped semiconductor wafer 1 (substrate, hereinafter referred to simply as “wafer 1”) onto which a protective tape is applied in the method of the embodiment. The wafer 1 is a silicon wafer or the like. Grid-like predetermined division lines 2 are formed on a surface of the wafer 1, and plural rectangular semiconductor chips (devices) 3 are defined by the predetermined division lines 2 on the surface of the wafer 1. Electronic circuits (for example, Integrated Circuits (ICs) and Large Scale Integrations (LSIs)), which are not shown in FIGS. 1A and 1B, are formed on surfaces of the semiconductor chips 3. The plural semiconductor chips 3 are formed on a device forming region 4 which is almost circular so as to be concentric with the wafer 1. A ring-shaped peripheral extra region 5 (non-device forming region), which has no semiconductor chip 3 formed thereon, is formed around the device forming region 4.

### 2. Thinning of Wafer

In the wafer 1 shown in FIGS. 1A and 1B, only portion of rear surface of the wafer 1, which corresponds to the device forming region 4, is thinned by grinding. In the grinding, as shown in FIGS. 1A and 1B, a protective tape 6 is applied onto the surface of the wafer 1 beforehand in order to protect the electronic circuits. For example, the protective tape 6 is a tape which has a base film and an adhesive coated on a surface of the base film. For example, the base film of the protective tape 6 is composed of polyolefin and has a thickness of about 70 to 200 μm. The adhesive is composed of acrylic resin and has a thickness of about 5 to 20 μm. A method for applying the protective tape onto the surface of the wafer 1 is freely selected.

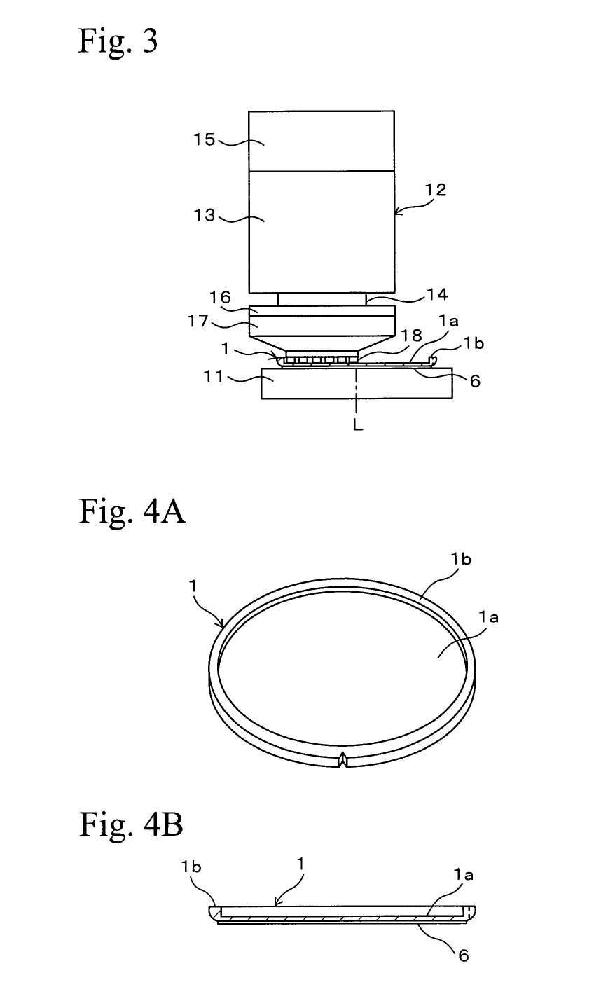

A grinding apparatus 10 shown in FIGS. 2 and 3 is desirably used for the grinding of the wafer 1. The grinding apparatus 10 is equipped with a chuck table 11 and a grinding unit 12. The chuck table 11 is a vacuum type one which rotates. The chuck table 11 has a disc-shape which is larger than the wafer 1, and it has an upper surface which is set to be horizontal and on which the wafer 1 is mounted. The wafer 1 is chucked and held on the upper surface of the chuck table 11 by vacuum operation. The chuck table 11 is rotated by a driving mechanism (not shown in the drawings) around an axial center of the chuck table 11.

The grinding unit 12 is equipped with a cylindrical spindle housing 13, a spindle 14, a motor 15, a flange 16, a cup wheel 17, and plural grinding stones 18. The spindle 14 is provided in the spindle housing 13. The cup wheel 17 is secured at an end portion of the spindle 14 via the flange 16. The grinding stones 18 are secured at a whole outer circumferential portion of lower surface of the cup wheel 17 so as to be arranged in a ring-shaped manner. In the grinding unit 12, when the spindle 14 is rotated by the motor 15, the cup wheel 17 is rotated, and the grinding stones 18 grind a work. An outer diameter of circular grinding locus of the grinding stones 18 is almost equal to a radius of the device forming region 4 of the wafer 1. The grinding unit 12 is shifted to be eccentric with the chuck table 11. The detail is shown in FIG. 3. That is, the relative position of the chuck table 11 and the grinding unit 12 is set such that an almost center portion of edge thickness (radius direction length) of the grinding stone 18, which is positioned the most proximate to the center of the chuck table 11 of the plural grinding stones 18, is positioned on a vertical line L on which the center of the chuck table 11 is positioned.

Only the portion of the rear surface of the wafer 1, which corresponds to the device forming region 4, is ground by the grinding apparatus 10 in the following manner. First, the wafer 1 is disposed on the upper surface of the chuck table 11, which is under vacuum operation, so as to be almost concentric therewith. In this case, the rear surface of the wafer 1 is exposed upward and the protective tape 6 closely contacts the upper surface of the chuck table 11. Thus, the wafer is held on the chuck table 11. Next, while the cup wheel 17 is rotated in high speed, the grinding unit 12 moves downwardly, and the all grinding stones 18 are pressed on the exposed rear surface of the wafer 1, the chuck table 11 is rotated. As a result, the portion of the rear surface of the wafer 1, which corresponds to the device forming region 4, is ground and thinned.

After the entire portion of the rear surface of the wafer 1, which corresponds to the device forming region 4, is uniformly ground so as to have a predetermined thickness (for example, about 200 to 100 μm or about 50 μm), the grinding unit 12 is moved upwardly, and the rotation of the chuck table 11 is stopped. As shown in FIGS. 4A and 4B, the wafer 1 is processed to have a recessed shape such that a recess 1a is formed at the portion of the rear surface of the wafer 1, which corresponds to the device forming region 4, and a ring-shaped peripheral reinforcing portion 1b is formed at a portion corresponding to the peripheral extra region 5 so as to have an initial thickness of the wafer 1 and project on the rear surface.

### 3. Applying of Protective Tape

In the wafer 1 in which the recess 1a is formed and the device forming region 4 is thinned, the following processing may be performed with heating. For example, a metal film composed of Au or the like is provided on the rear surface of the wafer 1 by deposition, sputtering, or the like. For example, impurities are diffused in the wafer 1 by ion implantation from the rear surface of the wafer 1. When the above processing is performed, the protective tape 6 is peeled from the surface of the wafer 1 in order to prevent occurrence of problem in which the protective tape 6 is melted and adhered to the surface of the wafer 1 by the heating. Since the peripheral reinforcing portion 1b is not ground in the above grinding, the rigidity of the wafer 1 is maintained even after the peeling of the protective tape 6, and handling (for example, carrying) of the wafer 1 is performed by holding the peripheral reinforcing portion 1b.

In the wafer 1 after the processing with the heating, the peripheral reinforcing portion 1b is finally removed by cutting or grinding. In this case, in order to protect the electronic circuits formed on the wafer 1, a protective tape is applied onto the surface of the wafer 1 again. A protective tape applying method will be explained hereinafter. This protective tape applying method is an embodiment according to the present invention.

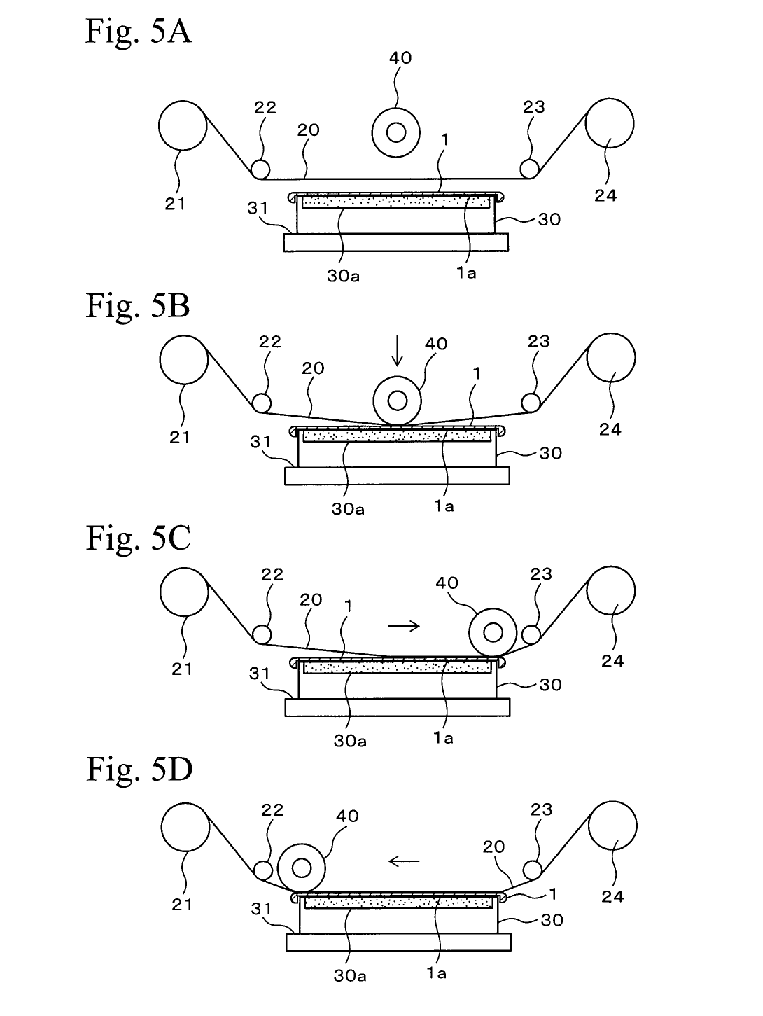

FIGS. 5A to 5D show the protective tape applying method of the embodiment in process order. As shown in FIGS. 5A to 5D, reference numeral 21 denotes a protective tape roller having a long transparent protective tape 20 which is wound in a roll form and is stored thereon. The protective tape 20 is wound off from the protective tape roller 21 such that an adhesive surface of the protective tape 21 faces downwardly. The protective tape 20 is wound on a winding roller 24 via pinch rollers 22 and 23, the winding roller 24 being disposed parallel to the protective tape roller 21. The pinch rollers 22 and 23 are disposed at the same height positions. A disc-shaped chuck table 30 is provided directly under the horizontal protective tape 20 strained between the pinch rollers 22 and 23. In this case, the protective tape 20 is the same tape as the above protective tape 6. That is, the protective tape 20 is a tape which has a base film and an adhesive coated on a surface of the base film. For example, the base film of the protective tape 20 is composed of polyolefin and has a thickness of about 70 to 200 μm. The adhesive is composed of acrylic resin and has a thickness of about 5 to 20 μm. The protective tape 20 has a width such that the protective tape 20 can sufficiently cover the entire surface of the wafer 1.

The chuck table 30 is a vacuum chuck type table and is provided on a table base 31 such that an upper surface of the chuck table 30 is horizontal. A porous vacuum chucking portion 30a is formed at an area of upper portion of the chuck table 30, the area being other than a circumferential edge thereof. The chuck table 30 has an outer diameter which is slightly smaller than an inner diameter of the recess 1a of the wafer 1. As shown in FIGS. 5A to 5D, the wafer 1 is set on the chuck table 30 such that the surface of the wafer 1 is exposed upward and the recess 1a of the wafer 1 is fitted to the upper portion of the chuck table 30. While the chuck table 30 is under vacuum operation, the wafer 1 is set on the chuck table 30 such that the recess 1a is fitted to the upper portion in the above manner and the air is absorbed from the vacuum chucking portion 30a, so that a bottom surface of the recess 1a is chucked on the upper surface of the chuck table 30. The surface of the wafer 1 held on the chuck table 30 in the above manner is horizontal. The protective tape 20 between the pinch rollers 22 and 23 horizontally faces the surface of the wafer 1, which is disposed on the chuck table 30, so to be slightly spaced from the surface of the wafer 1.

As shown in FIG. 5A, a pressing roller 40 is provided above the protective tape 20 disposed above the chuck table 30, and it has a rotational axis parallel to those of the rollers 21 to 24. The pressing roller 40 is elevatable and parallel movable between the left pinch roller 22 and the right pinch roller 23. The pressing roller 40 is a driven rotation roller. The pressing roller 40 rolls right or left while pressing the protective tape 20 onto the wafer 1 from the upside, so that the protective tape 20 is applied onto the wafer 1 by the pressing roller 40. The pressing roller 40 has at least a surface which is appropriately elastic so as to have affinity to the protective tape 20 and facilitate easily applying of the protective tape 20 onto the wafer 1. The pressing roller 40 has a pressing width (in this case, axial direction length) which is almost wider than a diameter of the wafer 1. The pressing roller 40 is disposed above the chuck table 30 so as be sufficiently rollable on the entire surface of the wafer 1.

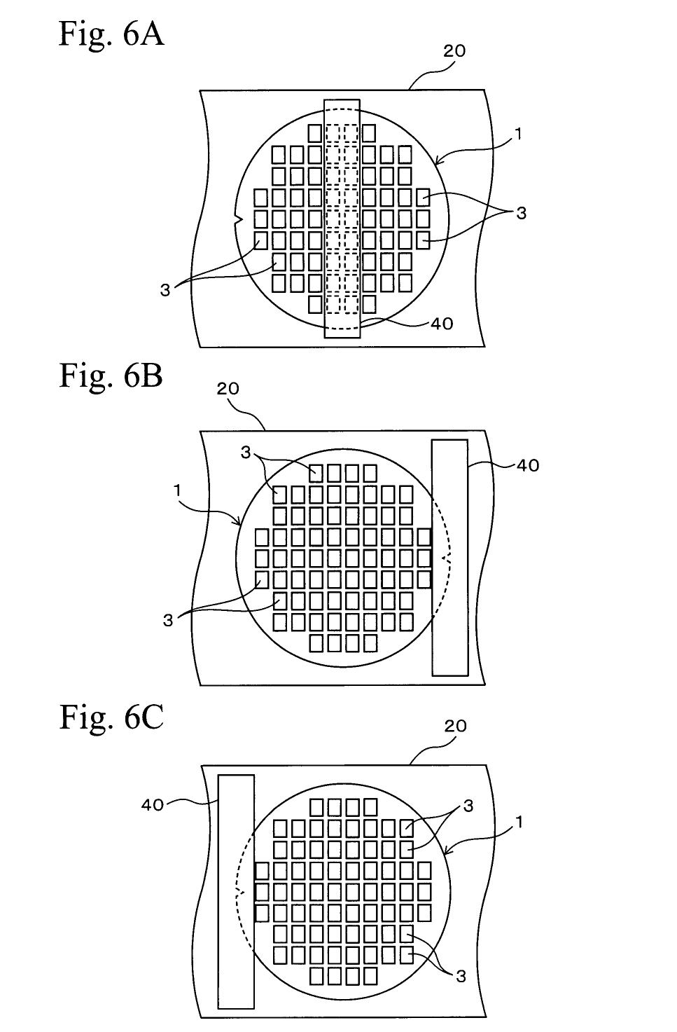

In order to apply the protective tape 20 on the surface of the wafer 1, first, vacuum operation of the chuck table 30 starts, the recess 1a of the wafer 1 is fitted to the chuck table 30, and the wafer 1 is chucked and held. Next, the winding roller 24 is rotated, the protective tape 20 is wound off from the protective tape roller 21. A lower surface of the protective tape 20, which is a fresh adhesive surface, faces the surface of the wafer 1 disposed on the chuck table 30. As shown in FIGS. 5B and 6A, the pressing roller 40 moves downwardly to a center portion of the wafer 1, and it presses the protective tape 20 onto the surface of the wafer 1 at a predetermined load.

As shown in FIGS. 5C and 6B, the pressing roller 40 rolls from the center portion of the wafer 1 to one end portion (right end portion in these drawings) of the wafer 1, so that the protective tape 20 is applied onto the almost half of the surface of the wafer 1. As shown in FIGS. 5D and 6C, while the pressing load is maintained to be constant, the pressing roller 40 moves in an opposite direction, and it rolls to the other end portion (left end portion in these drawings) of the wafer 1. Thus, the protective tape 20 is applied onto the entire surface of the wafer 1. After that, the pressing roller 40 moves upwardly from the wafer 1, and a cutter (not shown in the drawings) cuts the protective tape 20 circularly along a circumferential edge of the wafer 1. Thus, the applying of the protective tape 20 onto one wafer 1 is completed. The protective tape 20 is wound onto the winding roller 24 by a predetermined length approximately corresponding to a diameter of one wafer, a next new portion is disposed on the chuck table 30, and a next wafer 1 is set on the chuck table 30.

In the above method, since in the initial applying of the protective tape 20, the load is not provided on the end portion of the wafer 1 but is provided on the center portion of the wafer 1, the load is widely dispersed and becomes minimal. As a result, breakage of the end portion of the wafer 1, which is caused by locally providing the load thereto by the pressing roller 40, can be prevented, and the protective tape 20 can be reliably applied thereon. In the initial applying of the protective tape 20, providing of excessive load to the end portion of the wafer 1 is avoided, so that the load of the pressing roller 40 onto the wafer 1 can be constant in the rolling of the pressing roller 40. That is, while the load, which is not changed depending on applying width but is constant, is provided to the wafer 1 by the pressing roller 40, the applying of the protective tape 20 onto the wafer 1 can be easily performed by simply rolling the pressing roller 40. It is advantageous that the position of the wafer 1 pressed by the pressing roller be the center portion of the wafer 1 described above. Alternatively, even when the position is a position which is slightly away from the center portion of the wafer 1, that is, which is proximate to the center portion of the wafer 1, the same actions and effects described above can be obtained.

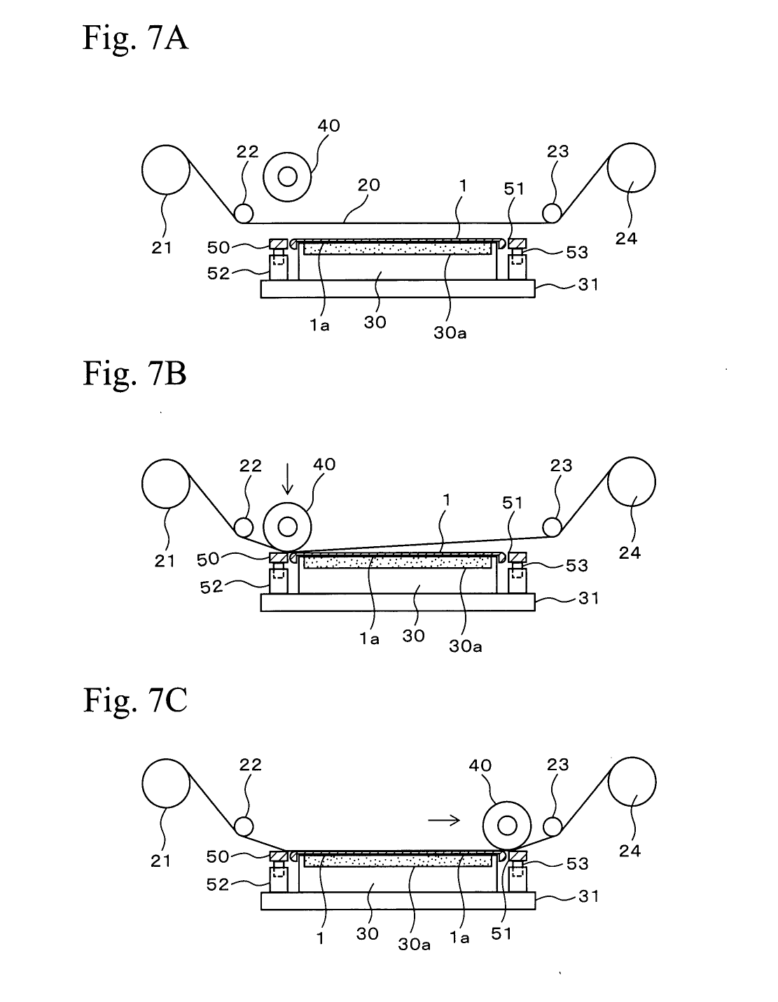

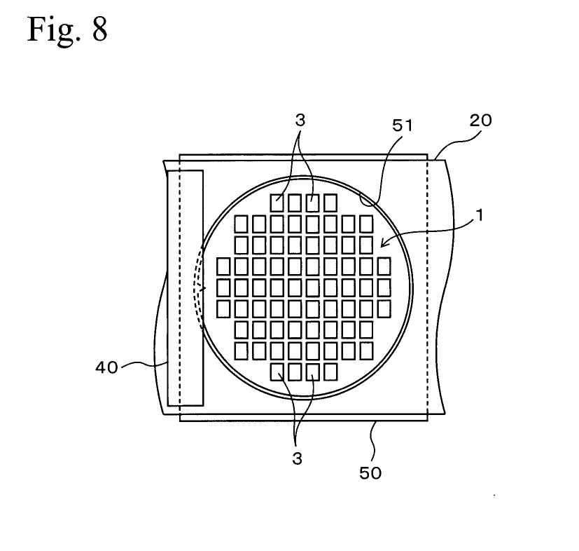

Next, another embodiment according to the present invention will be explained with reference to FIGS. 7A to 8.

In an applying method of this embodiment, a supporting plate (supporting member) 50 is disposed around the wafer 1 held on the chuck table 30 such that an upper surface of the supporting plate 50 has the same height as the surface of the wafer 1. The pressing roller 40 rolls on the supporting plate 50 too. The supporting plate 50 has a rectangular shape having a width equal to or wider than that of the protective tape 20. The supporting plate 50 has a circular hole 51 formed at a center portion thereof. The hole 51 is slightly larger than the outer diameter of the wafer 1, and the wafer 1 is provided in the hole 51. In order to easily peel the adhesive surface of the protective tape 20 from the supporting plate 50, fine convexoconcaves or fine grooves are formed by processing on the upper surface of the supporting plate 50.

As shown in FIGS. 7A to 7C, the supporting plate 50 is supported by an upper end of extensible rods 53 such that the upper surface of the supporting plate 50 is horizontal. The extensible rods 53 are provided on plural actuators 52 so as to be extensible upwardly, the actuators 52 being provided on the table base 31. The extensible rods 53 extend or contract together with each other, so that the supporting plate 50 moves vertically around the wafer 1 while the upper surface of the supporting plate 50 is maintained to be horizontal.

In the applying method for the protective tape 20 which uses the supporting plate 50, first, the extensible rods 53 appropriately extend or contract, so that as shown in FIG. 7A, the upper surface of the supporting plate 50 is set to be flush with the surface (upper surface) of the wafer 1 held on the chuck table 30. In the same manner as the above embodiment, the wafer 1 is held on the chuck table 30, and the protective tape 20 faces the wafer 1. Next, as shown in FIG. 7B, the pressing roller 40, which moved above one end portion (left end portion shown in FIGS. 7A to 8) of the wafer 1, moves downwardly, and it presses the protective tape 20 onto the end portion of the wafer 1. In this initial applying of the protective tape 20, both end portions of the pressing roller 40 are also disposed on the upper surface of the supporting plate 50, so that the pressing roller 40 presses the supporting plate 50 at the same load as that on the wafer 1.

Next, while the pressing load of the pressing roller 40 is maintained to be constant, as shown in FIG. 7C, the pressing roller 40 rolls to the other end portion (right end portion shown in FIGS. 7A to 8) of the wafer 1. In the rolling of the pressing roller 40, both end portions of the pressing roller 40 are always positioned on the supporting plate 50. The pressing roller 40 for pressing the protective tape 20 rolls on the entire surface of the wafer 1, so that the protective tape 20 is applied onto the surface of the wafer 1. After that, in the same manner as the above embodiment, the pressing roller 40 moves upwardly from the wafer 1, a cutter (not shown in the drawings) cuts the protective tape 20 circularly along a circumferential edge of the wafer 1, and the applying of the protective tape 20 onto one wafer 1 is completed. Since unnecessary portion of the protective tape 20 remains on the upper surface of the supporting plate 50 after the cutting of the protective tape 20, the portion thereof is peeled and removed therefrom. In this case, since the fine convexoconcaves or the fine grooves are formed on the upper surface of the supporting plate 50 by the processing as described above, even when the protective tape 20 is pressed onto the upper surface of the supporting plate 50, the protective tape 20 is not easily adhered thereto, and is thereby easily peeled therefrom.

In the applying method of the embodiment, from the initial applying to the end applying of the protective tape 20 onto the entire surface of the wafer 1, the pressing roller 40 rolls on the surface of the wafer 1 and the surface of the supporting plate 50 which is around the wafer 1. Since the pressing roller 40 rolls on the surfaces of the wafer 1 and the supporting plate 50 which are flush with each other, the load provided from the pressing roller 40 to the wafer 1 is dispersed. Therefore, the load provided to the wafer 1 is not excessive. As a result, the breakage of the wafer 1 can be prevented, so that the pressing roller 40 can roll at a constant pressing load.

The rolling pattern of the pressing roller 40 is not limited to the above action in which the pressing roller 40 rolls from the end portion of the wafer 1 to the other end portion thereof. That is, the position of the wafer 1, onto which the pressing roller 40 initially presses the protective tape 20 by moving downwardly, is freely selected. In this case, the pressing roller rolls on the entire surface of the wafer 1 from the initial pressing position in order that the supporting plate 50 receive and disperse the initial pressing load of the pressing roller and this pressing load to the wafer 1 be not excessive.

What is claimed is:

1. A protective tape applying method comprising:
preparing a substrate which has plural devices formed on a surface of the substrate;
holding the substrate on a chuck table such that a rear surface of the substrate is chucked by the chuck table and the surface of the substrate is exposed;
straining a protective tape on the surface of the substrate held by the chuck table such that the protective tape faces the surface of the substrate;
pressing the protective tape on a center portion of the substrate or a portion proximate to the center portion by using a pressing roller having a pressing width which is at least equal to or wider than a diameter of the substrate; and
rolling the pressing roller on the substrate while the pressing roller presses the protective tape on the substrate, so that the protective tape is applied onto the entire surface of the substrate.

2. A protective tape applying method comprising:
preparing a substrate which has plural devices formed on a surface of the substrate;
holding the substrate on a chuck table such that a rear surface of the substrate is chucked by the chuck table and the surface of the substrate is exposed;
straining a protective tape on the surface of the substrate held by the chuck table such that the protective tape faces the surface of the substrate;
providing a support member around the substrate, the support member having a surface which is flush with the surface of the substrate; and
rolling a pressing roller on the substrate while the pressing roller presses the protective tape on the substrate and the supporting member which is around the substrate, the pressing roller having a pressing width which is at least equal to or wider than a diameter of the substrate, so that the protective tape is applied onto the entire surface of the substrate.

3. A protective tape applying method according to the claim 1, wherein
the substrate has a device forming region on which the devices are formed, and at least the device forming region of the substrate has a thickness of 200 μm or less.

4. A protective tape applying method according to the claim 2, wherein
the substrate has a device forming region on which the devices are formed, and at least the device forming region of the substrate has a thickness of 200 μm or less.

5. A protective tape applying method according to the claim 1, wherein
the substrate has a non-device forming region which is formed around the device forming region and has no device, and
a region of the rear surface of the substrate, which corresponds to the device forming region, is formed to have a recessed shape which is thinner than the non-device forming region.

6. A protective tape applying method according to the claim 2, wherein
the substrate has a non-device forming region which is formed around the device forming region and has no device, and
a region of the rear surface of the substrate, which corresponds to the device forming region, is formed to have a recessed shape which is thinner than the non-device forming region.
